(19) United States
(12) Patent Application Publication
(10) Pub. No.: US 2025/0140695 A1
(43) Pub. Date: May 1, 2025

(54) SEMICONDUCTOR PACKAGE WITH A BACKSIDE POWER DISTRIBUTION NETWORK

(71) Applicant: SAMSUNG ELECTRONICS CO., LTD., Suwon-si (KR)

(72) Inventors: Sunggu KANG, Suwon-si (KR); Jaechoon KIM, Suwon-si (KR); Sungho MUN, Suwon-si (KR)

(73) Assignee: SAMSUNG ELECTRONICS CO., LTD., Suwon-si (KR)

(21) Appl. No.: 18/927,458

(22) Filed: Oct. 25, 2024

(30) Foreign Application Priority Data
Oct. 27, 2023 (KR) 10-2023-0145935

(51) Int. Cl. H01L 23/528; H01L 23/00; H01L 23/31; H01L 23/367; H01L 23/48; H01L 23/498; H01L 25/065; H10B 80/00

(52) U.S. Cl. CPC H01L 23/5286; H01L 23/3128; H01L 23/3135; H01L 23/3672; H01L 23/481; H01L 23/49833; H01L 23/49838; H01L 23/5283; H01L 24/16; H01L 25/0655; H01L 2224/16245; H01L 2924/1815; H10B 80/00

(57) ABSTRACT

A semiconductor package includes a first redistribution layer substrate having a lower conductive structure; a first semiconductor chip and a second semiconductor chip electrically connected to the first redistribution layer substrate and arranged side-by-side on the first redistribution layer substrate; and an interposer disposed over a portion of the first semiconductor chip and a portion of the second semiconductor chip to electrically connect the first semiconductor chip to the second semiconductor chip, wherein the first semiconductor chip comprises a rear power distribution network structure in a lower portion of the first semiconductor chip, and the second semiconductor chip comprises a rear power distribution network structure in a lower portion of the second semiconductor chip.

### CROSS-REFERENCE TO RELATED APPLICATION

This application is based on and claims priority under 35 U.S.C. § 119 to Korean Patent Application No. 10-2023-0145935, filed on Oct. 27, 2023, in the Korean Intellectual Property Office, the disclosure of which is incorporated by reference herein in its entirety.

### BACKGROUND

### 1. Field

The embodiments of the present disclosure relate to a semiconductor package, and more particularly, to a semiconductor package including a plurality of semiconductor chips.

### 2. Description of Related Art

As the electronics industry develops rapidly, electronic devices are becoming more compact and lightweight in response to user demands. As electronic devices become smaller and lighter, semiconductor packages used therein are also smaller and lighter, requiring a high integration of semiconductor devices.

Accordingly, semiconductor packages including a plurality of semiconductor chips has been developed to provide multiple functions. However, when a plurality of semiconductor chips are included, the necessary power must be provided to each semiconductor chip, and communication performance between semiconductor chips must be secured. However, current devices do not adequately provide power to the semiconductor chips or facilitate proper communication performance between the semiconductor chips.

### SUMMARY

The embodiments of the present disclosure provide a semiconductor package including a plurality of semiconductor chips with improved operation speed and operation reliability.

In addition, the embodiments of the present disclosure are not limited thereto, and other embodiments may be clearly understood by those skilled in the art from the description below.

According to one or more embodiments, a semiconductor package comprises: a first redistribution layer substrate having a lower conductive structure; a first semiconductor chip and a second semiconductor chip electrically connected to the first redistribution layer substrate and arranged side-by-side on the first redistribution layer substrate; and an interposer disposed over a portion of the first semiconductor chip and a portion of the second semiconductor chip to electrically connect the first semiconductor chip to the second semiconductor chip, wherein the first semiconductor chip comprises a power distribution network structure, and the second semiconductor chip comprises a power distribution network structure.

According to one or more embodiments, a semiconductor package comprises: a first redistribution layer substrate having a lower conductive structure; a first semiconductor chip and a second semiconductor chip electrically connected to the first redistribution layer substrate and arranged side-by-side on the first redistribution layer substrate; and an interposer disposed over the first semiconductor chip and the second semiconductor chip so as to completely cover a surface of the first semiconductor chip and a surface of the second semiconductor chip and electrically connecting the first semiconductor chip to the second semiconductor chip, wherein the first semiconductor chip and the second semiconductor chip each comprise a power distribution network structure.

According to one or more embodiments, a semiconductor package comprises a first redistribution layer substrate comprising a conductive structure; a plurality of external connection terminals disposed at a bottom of the first redistribution layer substrate; a first semiconductor chip and a second semiconductor chip electrically connected to the first redistribution layer substrate and arranged side-by-side on the first redistribution layer substrate; a first expansion layer disposed on the first redistribution layer substrate and outside the first semiconductor chip and the second semiconductor chip; a first molding member surrounding the first semiconductor chip and the second semiconductor chip, the first molding member filling a space between the first semiconductor chip and the first expansion layer and a space between the first semiconductor chip and the first expansion layer, a second redistribution layer substrate disposed on the first semiconductor chip, the second semiconductor chip, and the first expansion layer, the second redistribution layer comprising a conductive structure; an interposer disposed on the second redistribution layer substrate, the interposer disposed to vertically overlap a portion of the first semiconductor chip and a portion of the second semiconductor chip with the second redistribution layer substrate therebetween, the interposer electrically connecting the first semiconductor chip to the second semiconductor chip; a second expansion layer disposed on the second redistribution layer substrate, the second expansion layer disposed to overlap another portion of the first semiconductor chip and another portion of the second semiconductor chip, the second expansion layer disposed outside the interposer; a second molding member surrounding an upper portion and sides of the interposer, the second molding member filling a space between the interposer and the second expansion layer; and a third redistribution layer substrate disposed on the second expansion layer and the interposer, the third redistribution layer comprises a second upper conductive structure, wherein the first semiconductor chip comprises a power distribution network structure, and the second semiconductor chip comprises a power distribution network structure, and wherein the second redistribution layer substrate is electrically connected to the first expansion layer, the first semiconductor chip, and the second semiconductor chip at a first portion of the second redistribution layer substrate and is electrically connected to the second expansion layer and the interposer at a second portion of the second redistribution layer substrate.

### BRIEF DESCRIPTION OF DRAWINGS

Embodiments of the present disclosure will be more clearly understood from the following detailed description taken in conjunction with the accompanying drawings in which:

FIG. 1 is a cross-sectional view of a semiconductor package according to one or more embodiments;

FIG. 2 is a detailed cross-sectional view of a first semiconductor chip according to one or more embodiments;

FIG. 3 is a cross-sectional view of a semiconductor package including a first semiconductor chip and a second semiconductor chip, according to one or more embodiments;

FIG. 4 is a cross-sectional view of a semiconductor package including a heat dissipation structure, according to one or more embodiments;

FIG. 5 is a cross-sectional view showing a semiconductor package according to one or more embodiments;

FIG. 6 is a cross-sectional view showing a semiconductor package further including a heat dissipation structure in the semiconductor package of FIG. 5;

FIG. 7 is a cross-sectional view showing a semiconductor package according to one or more embodiments;

FIG. 8 is a cross-sectional view showing a semiconductor package further including a heat dissipation structure in the semiconductor package of FIG. 7;

FIG. 9 is a cross-sectional view illustrating the operation of a first semiconductor chip and a second semiconductor chip in a semiconductor package according to one or more embodiments; and

FIGS. 10A to 10I are cross-sectional views schematically showing the process of manufacturing the semiconductor package of FIG. 4, according to one or more embodiments.

### DETAILED DESCRIPTION

Hereinafter, embodiments of the present disclosure will be described in detail with reference to the attached drawings. The same reference numerals are used for the same components in the drawings, and duplicate descriptions thereof are omitted.

Hereinafter, example embodiments will be described with reference to the accompanying drawings. Hereinafter, terms, such as ‘top,’ ‘upper portion,’ ‘upper surface,’ ‘bottom,’ ‘lower portion,’ ‘lower surface,’ and ‘side surface’ may be understood as illustrated in the drawings, except for cases indicated by reference numerals.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

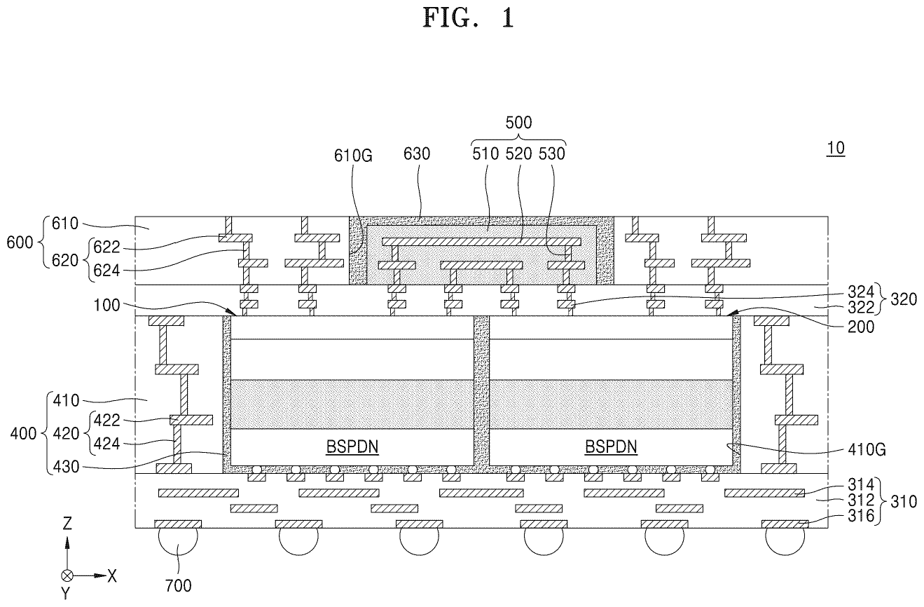

FIG. 1 is a cross-sectional view of a semiconductor package according to one or more embodiments.

Referring to FIG. 1, a semiconductor package 10 according to one or more embodiments may include a first semiconductor chip 100, a second semiconductor chip 200, a lower redistribution layer substrate 310, a first upper redistribution layer substrate 320, a first expansion layer 400, an interposer 500, a second expansion layer 600, and a plurality of external connection terminals 700. As understood by one of ordinary skill in the art, a redistribution layer may be metal (e.g. copper) interconnects that electrically connect one part of a semiconductor package or chip to another. A redistribution layer may allow for creation of additional wiring on a chip, enabling the redistribution of I/O pads to different locations. These features provide enhanced chip-to-chip bonding by providing more flexible options for connecting integrated circuits (ICs) to other components.

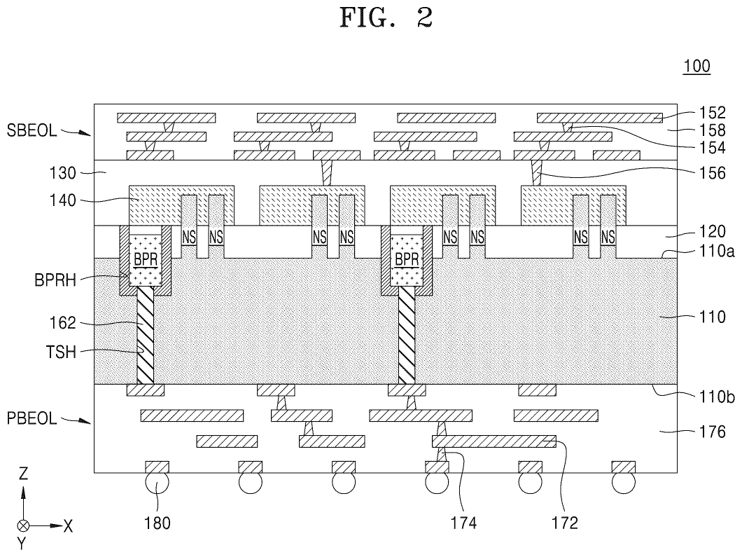

The first semiconductor chip 100 and the second semiconductor chip 200 may be arranged side-by-side on the lower redistribution layer substrate 310. For example, the first semiconductor chip 100 and the second semiconductor chip 200 may be arranged to be spaced apart from each other at a predetermined distance on the lower redistribution layer substrate 310. The first semiconductor chip 100 and the second semiconductor chip 200 may each have a backside power distribution network (BSPDN) structure disposed in the lower portion of the first semiconductor chip 100 and the second semiconductor chip 200. Each of the BSPDNs may receive power through the lower redistribution layer substrate 310. A detailed description of the first semiconductor chip 100 and the second semiconductor chip 200 according to one or more examples is described below with reference to FIG. 2.

The lower redistribution layer substrate 310 may be disposed in the lower portion of the first semiconductor chip 100 and the second semiconductor chip 200, and may redistribute chip pads of the first semiconductor chip 100 and chip pads of the second semiconductor chip 200 to an external area. In one or more examples, the lower redistribution layer substrate 310 may include a lower body insulating layer 312 and a lower conductive structure 314.

The lower body insulating layer 312 may be formed of an insulating material, for example, photo imageable dielectric (PID) resin, and may further include an inorganic filler. However, the material of the lower body insulating layer 312 is not limited to the above-described materials, and may include any other suitable materials known to one of ordinary skill in the art. The lower body insulating layer 312 may have a multi-layer structure depending on the multi-layer structure of the lower conductive structure 314. When the lower body insulating layer 312 has a multi-layer structure, the lower body insulating layer 312 may be formed of the same material or different materials.

The lower conductive structure 314 may include multiple layers that may be connected to each other through vias. The lower conductive structure 314 may be made of metal or an alloy thereof.

In one or more embodiments, the lower redistribution layer substrate 310 may further include a plurality of external connection pads 316 disposed at the bottom of the lower redistribution layer substrate 310. The external connection pad 316 may be formed to be electrically connected to the lower conductive structure 314. In one or more examples, the lower redistribution layer substrate 310 may not include the plurality of external connection pads 316, and one or more of the lower conductive structures 314 may function as a plurality of external connection pads.

In one or more examples, the plurality of external connection terminals 700 may be disposed on the lower surface of the lower body insulating layer 312. The external connection terminal 700 may be disposed on the external connection pad 316 formed on the lower surface of the lower body insulating layer 312. For example, the external connection terminal 700 may be a bump or solder ball. The external connection terminal 700 may be electrically connected to the first semiconductor chip 100 and the second semiconductor chip 200 through the lower conductive structure 314 of the lower redistribution layer substrate 310.

The first expansion layer 400 may be disposed outside the first semiconductor chip 100 and the second semiconductor chip 200 on the lower redistribution layer substrate 310. For example, the first semiconductor chip 100 and the second semiconductor chip 200 may be disposed in an inner space 410G of the first expansion layer 400.

In one or more examples, the first expansion layer 400 may include a first insulating layer 410 and a plurality of first conductive connection structures 420 buried in the first insulating layer 410. For example, the first expansion layer 400 may be an embedded trace substrate (ETS) in which a circuit pattern is buried in an insulating material.

In one or more examples, the plurality of first conductive connection structures 420 may include a plurality of first conductive layers 422 and a plurality of first vertical vias 424. The plurality of first conductive layers 422 may extend in a horizontal direction (e.g., X direction and/or Y direction) on the first insulating layer 410, and the plurality of first vertical vias 424 may penetrate the first insulating layer 410 to connect the plurality of first conductive layers 422 in a vertical direction (e.g., Z direction) to one another.

For example, the first insulating layer 410 may include a plurality of layers, and a plurality of first conductive layers 422 may be formed on the upper or lower surface of each of the plurality of first insulating layers 410. The plurality of first vertical vias 424 may penetrate the first insulating layer 410 to electrically connect the plurality of first conductive layers 422 at different levels to one other. For example, the plurality of first conductive layers 422 and the plurality of first vertical vias 424 may be made of copper, nickel, stainless steel, or beryllium copper.

In one or more examples, the first expansion layer 400 may surround the first semiconductor chip 100 and the second semiconductor chip 200. The inner space 410G formed in the first expansion layer 400 may be formed as an opening or cavity of the first expansion layer 400. The inner space 410G may be formed in a partial area of the first expansion layer 400, for example, in the center area of the first expansion layer 400. The inner space 410G may be recessed from the upper surface of the first expansion layer 400 to a predetermined depth, or may be formed open. For example, the horizontal width and horizontal area of the inner space 410G may have values greater than the sum of the horizontal widths and the sum of the horizontal areas of the first semiconductor chip 100 and the second semiconductor chip 200, respectively.

In one or more examples, a first molding member 430 may be disposed on the lower redistribution layer substrate 310 to surround the first semiconductor chip 100 and the second semiconductor chip 200. The first molding member 430 may fill the space between the first expansion layer 400, the first semiconductor chip 100, and the second semiconductor chip 200. For example, the first molding member 430 may be formed from thermosetting resin such as epoxy resin, thermoplastic resin such as polyimide, or resin including a reinforcing material such as an inorganic filler in the thermosetting resin or the thermoplastic resin, specifically, ajinomoto build-up film (ABF), flame retardant (FR)-4, bismaleimide-triazine (BT), etc. In one or more examples, the first molding member 430 may be formed from a molding material, such as epoxy mold compound (EMC), or a photosensitive material such as photo imageable encapsulant (PIE).

In one or more examples, the first molding member 430 may be arranged to cover only the lower surface and side surfaces of the first semiconductor chip 100 and the second semiconductor chip 200. The upper surface of the first molding member 430, the upper surface of the first semiconductor chip 100, the upper surface of the second semiconductor chip 200, and the upper surface of the first expansion layer 400 may form the same plane.

In one or more examples, the first upper redistribution layer substrate 320 may be disposed on the first semiconductor chip 100, the second semiconductor chip 200, and the first expansion layer 400. The first upper redistribution layer substrate 320 may redistribute the upper wiring structures of the first semiconductor chip 100, the upper wiring structure of the second semiconductor chip 200, and the plurality of first conductive connection structures 420. In one or more examples, the first upper redistribution layer substrate 320 may include a first upper body insulating layer 322 and a first upper conductive structure 324.

The first upper body insulating layer 322 and the first upper conductive structure 324 may correspond to the lower body insulating layer 312 and the lower conductive structure 314, respectively. The first upper body insulating layer 322 may be formed of an insulating material, for example, PID resin, and may further include an inorganic filler. The first upper conductive structure 324 may include multiple layers that may be connected to each other through vias.

In one or more examples, one or more of the vias included in the first upper conductive structure 324 may be formed to be connected to an upper wiring structure SBEOL of the first semiconductor chip 100 and the second semiconductor chip 200, which are described below. The first upper conductive structure 324 may be connected to the plurality of first conductive connection structures 420 of the first expansion layer 400.

The interposer 500 may be disposed on the first semiconductor chip 100 and the second semiconductor chip 200 and may electrically connect the first semiconductor chip 100 and the second semiconductor chip 200 to each other. The interposer 500 may be arranged to overlap a portion of the first semiconductor chip 100 and a portion of the second semiconductor chip 200. In one or more examples, the portion of the first semiconductor chip 100 and the portion of the second semiconductor chip 200 overlapped by the interposer 500 may be equal to each other. In one or more examples, the portion of the first semiconductor chip 100 and the portion of the second semiconductor chip 200 overlapped by the interposer 500 may be different sizes.

The interposer 500 may include a silicon substrate 510, a wiring line 520, and a wiring via 530. The wiring line 520 may include a plurality of layers within the silicon substrate 510. The wiring via 530 may penetrate at least a portion of the silicon substrate 510 to electrically connect the wiring lines 520. For example, the interposer 500 may be a silicon bridge.

The interposer 500 may be disposed on the first upper redistribution layer substrate 320. The interposer 500 may be disposed on the first upper redistribution layer substrate 320 to vertically overlap a portion of the first semiconductor chip 100 and a portion of the second semiconductor chip 200. For example, the interposer 500 may be located in the center of the first semiconductor chip 100 and the second semiconductor chip 200 and may be arranged to overlap the first semiconductor chip 100 and the second semiconductor chip 200 by the same area. The interposer 500 may electrically connect the first semiconductor chip 100 and the second semiconductor chip 200 to each other through the first upper conductive structure 324 of the first upper redistribution layer substrate 320.

The second expansion layer 600 may be disposed outside the interposer 500 on the first upper redistribution layer substrate 320. The second expansion layer 600 may be disposed on the first upper redistribution layer substrate 320 to overlap the other portion of the first semiconductor chip 100 and the other portion of the second semiconductor chip 200. For example, the interposer 500 may be disposed in the inner space 610G of the second expansion layer 600, and outside the interposer 500, the second expansion layer 600 may vertically overlap a portion of the first semiconductor chip 100 and a portion of the second semiconductor chip 200 that is not overlapped by the interposer 500.

The second expansion layer 600 may have the same structure as the first expansion layer 400. In one or more examples, the second expansion layer 600 may include a second insulating layer 610 and a plurality of second conductive connection structures 620 embedded in the second insulating layer 610. For example, the second expansion layer 600 may be an ETS with a circuit pattern buried in an insulating material.

The plurality of second conductive connection structures 620 may include a plurality of second conductive layers 622 and a plurality of second vertical vias 624. The plurality of second conductive layers 622 may extend in a horizontal direction (e.g., X direction and/or Y direction) on the second insulating layer 610, and the plurality of second vertical vias 624 may penetrate the second insulating layer 610 to connect the plurality of second conductive layers 622 in the vertical direction (e.g., Z direction) to one another.

For example, the second insulating layer 610 may include a plurality of layers, and the plurality of second conductive layers 622 may be formed on the upper or lower surface of each of the plurality of second insulating layers 610. The plurality of second vertical vias 624 may penetrate the second insulating layer 610 to electrically connect the plurality of second conductive layers 622 at different levels to one another. For example, the plurality of second conductive layers 622 and the plurality of second vertical vias 624 may be made of copper, nickel, stainless steel, or beryllium copper.

In one or more examples, the second expansion layer 600 may surround the interposer 500. The inner space 610G formed in the second expansion layer 600 may be formed as an opening or cavity of the second expansion layer 600. The inner space 610G may be formed in a partial area of the second expansion layer 600, for example, in the central area of the second expansion layer 600. The inner space 610G may be recessed from the upper surface of the second expansion layer 600 to a predetermined depth or may be formed open. For example, the horizontal width and horizontal area of the inner space 610G may have greater values than the horizontal width and horizontal area of the interposer 500, respectively.

The second molding member 630 may be disposed on the first upper redistribution layer substrate 320 to surround the interposer 500. The second molding member 630 may fill the space between the second expansion layer 600 and the interposer 500. In one or more examples, the second molding member 630 may include the same material as the first molding member 430. In one or more examples, the second molding member 630 may include a material different from that of the first molding member 430.

In one or more examples, the second molding member 630 may be arranged to cover the upper and side surfaces of the interposer 500. The upper surface of the second molding member 630 may form the same plane as the upper surface of the plurality of second conductive connection structures 620.

FIG. 2 is a detailed cross-sectional view of a first semiconductor chip according to one or more embodiments.

The first semiconductor chip 100 may have the same structure as the second semiconductor chip 200. Hereinafter, the structure is described focusing on the first semiconductor chip 100, but the second semiconductor chip 200 may also be described as having the same structure as the first semiconductor chip 100. As understood by one of ordinary skill in the art, the structure of the second semiconductor chip 200 may be different than the structure of the first semiconductor chip.

Referring to FIG. 2, the first semiconductor chip 100 may include a semiconductor substrate 110 having a front side surface 110a and a back side surface 110b facing each other, and a plurality of nanosheet regions NS protruding upward from the front side surface 110a of the semiconductor substrate 110. The front side surface 110a of the semiconductor substrate 110 may be referred to as the main surface of the semiconductor substrate 110. Each of the front side surface 110a and the back side surface 110b of the semiconductor substrate 110 may extend in a first horizontal direction (e.g., X direction) and a second horizontal direction (e.g., Y direction).

In one or more examples, the plurality of nanosheet regions NS may protrude upward in the vertical direction (Z direction) from the main surface of the semiconductor substrate 110, that is, the front side surface 110a of the semiconductor substrate 110. The semiconductor substrate 110 may include a semiconductor material, such as silicon (Si) or germanium (Ge), or a compound semiconductor material, such as silicon germanium (SiGe), silicon carbide (SiC), gallium arsenide (GaAs), indium arsenide (InAs), or indium phosphide (InP). The semiconductor substrate 110 may include a conductive region, for example, a well doped with an impurity or a structure doped with an impurity. In one or more embodiments, the plurality of nanosheet regions NS may be arranged at a constant pitch in the first horizontal direction (X direction) and extend parallel to each other in the second horizontal direction (Y direction).

A device isolation film 120 may be formed between each of the plurality of nanosheet regions NS, covering both sidewalls of the lower ends of the plurality of nanosheet regions NS. The device isolation film 120 may be made of, for example, oxide, nitride, or oxynitride.

On the semiconductor substrate 110, a plurality of gate lines 140 may extend in a direction intersecting with the plurality of nanosheet regions NS. In one or more embodiments, the plurality of gate lines 140 may extend in the first horizontal direction (X direction). A gate insulating film may be between the gate line 140 and the nanosheet region NS.

The gate line 140 may have a structure in which a metal nitride layer, a metal layer, a conductive capping layer, and a gap-fill metal film are sequentially stacked. The metal nitride layer and the metal layer may include at least one metal selected from titanium (Ti), tantalum (Ta), tungsten (W), ruthenium (Ru), niobium (Nb), molybdenum (Mo), and hafnium (Hf). The gap-fill metal film may be made of a W film or an Al film. Each gate line 140 may include a work function metal-containing layer. The work function metal-containing layer may include at least one metal selected from titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). In one or more embodiments, the gate line 140 may include a stacked structure of TiAlC/TiN/W, a stacked structure of TiN/TaN/TiAlC/TiN/W, or a stacked structure of TiN/TaN/TiN/TiAlC/TiN/W, or any other suitable stacked structure known to one of ordinary skill in the art.

An interlayer insulating layer 130 may cover the device isolation film 120 and the plurality of gate lines 140.

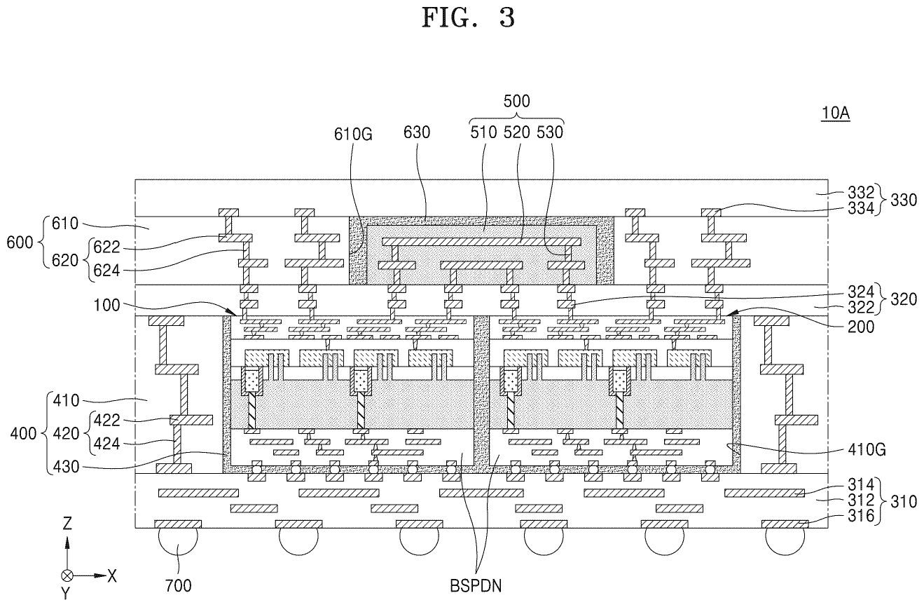

An upper wiring structure SBEOL may be disposed on the interlayer insulating layer 130. Referring to FIG. 3, the upper wiring structure SBEOL may be electrically connected to the interposer 500. The upper wiring structure SBEOL may include a plurality of upper wiring lines 152, a plurality of upper wiring vias 154, a plurality of connection vias 156, and an insulating layer 158 between the upper interconnections surrounding the upper wiring lines 152 and the upper wiring vias 154. The plurality of upper wiring vias 154 may electrically connect upper wiring lines 152 located at different vertical levels among the plurality of upper wiring lines 152 (e.g., upper wiring lines 152 located on different wiring layers). The plurality of connection vias 156 may electrically connect the plurality of upper wiring lines 152 to the plurality of gate lines 140. In one or more embodiments, some of the plurality of upper wiring lines 152 may function as a plurality of lower chip connection pads.

The plurality of upper wiring lines 152, the plurality of upper wiring vias 154, and the plurality of connection vias 156 may include metal materials such as copper (Cu), aluminum (Al), and tungsten (W). The insulating layer 158 between the upper interconnections may include a high density plasma (HDP) oxide film, tetraethyl orthosilicate (TEOS) oxide film, tonen silazene (TOSZ), spin on Glass (SOG), undoped silica glass (USG), or low-k dielectric layer, etc.

A passivation layer may be disposed on the upper wiring structure SBEOL. The passivation layer may be used as an etch stop layer in the process of manufacturing a semiconductor package including the first semiconductor chip 100. For example, the passivation layer may be made of silicon nitride.

A buried power rail BPR may be disposed inside the semiconductor substrate 110. The buried power rail BPR may be made of a conductive material, such as metal. The buried power rail BPR may be placed within a buried rail hole BPRH.

The buried rail hole BPRH may extend into the semiconductor substrate 110 through the device isolation layer 120. The plurality of buried rail holes BPRH may extend between the plurality of gate lines 140 and a plurality of micro through electrodes 162. The plurality of buried rail holes BPRH may be arranged to be spaced apart from the nanosheet region NS. The plurality of buried power rails BPR may be disposed within the plurality of buried rail holes BPRH.

A buried rail insulating layer made of nitride may be on the inner surface of the buried rail hole BPRH. For example, the buried rail insulating layer may be between the buried power rail BPR and the semiconductor substrate 110. In one or more examples, the buried rail insulating layer extends from between the buried power rail BPR and the semiconductor substrate 110 to between the buried power rail BPR and the device isolation layer 120 and may contact the lower surface of the gate line 140 and the lower surface of the interlayer insulating layer 130.

In one or more examples, the buried power rail BPR may be spaced apart from the plurality of nanosheet regions NS and disposed in the buried rail hole BPRH. The buried power rail BPR may be disposed within the buried rail hole BPRH between the gate line 140 and the micro through electrode 162.

In one or more examples, the buried power rail BPR may include a rail barrier film that covers at least portion of the inner surface and at least portion of the bottom of the buried rail hole BPRH, and a rail filling layer that covers the rail barrier film and fills at least portion of the buried rail hole BPRH. For example, the rail barrier film may include titanium nitride (TiN), and the rail filling layer may include tungsten (W) or ruthenium (Ru).

In one or more embodiments, the buried power rail BPR may only fill the lower portion of the buried rail hole BPRH, and the upper portion of the buried rail hole BPRH may be filled with a buried insulating layer. A power via penetrating the buried insulating layer may be between the buried power rail BPR and the gate line 140 to electrically connect the buried power rail BPR to the gate line 140.

A through hole TSH may extend into the semiconductor substrate 110 from the backside surface 110b of the semiconductor substrate 110. The through hole TSH may communicate with the buried rail hole BPRH. The through hole TSH may be filled by the micro through electrode 162. In one or more examples, the through hole TSH may be filled with a via insulating film between the semiconductor substrate 110 and the micro through electrode 162. The via insulation film may be made of an oxide film, a nitride film, a carbonization film, a polymer, or a combination thereof.

The micro through electrode 162 may include a conductive plug that contacts the buried power rail BPR and extends to the backside surface of the semiconductor substrate 110, and a conductive barrier film surrounding the conductive plug. The conductive plug may include Cu or W. For example, the conductive plug may be made of Cu, CuSn, CuMg, CuNi, CuZn, CuPd, CuAu, CuRe, CuW, W, or W alloy, or any other suitable material known to one of ordinary skill in the art. For example, the conductive plug includes one or more of Al, Au, Be, Bi, Co, Cu, Hf, In, Mn, Mo, Ni, Pb, Pd, Pt, Rh, Ta, Te, Ti, W, Zn, and Zr and may include one or more laminated structures. The conductive barrier film may include at least one material selected from W, WN, WC, Ti, TiN, Ta, TaN, Ru, Co, Mn, WN, Ni, and NiB and may be a single layer or a multilayer, but is not limited thereto.

A lower wiring structure PBEOL may be disposed on the backside surface 110b of the semiconductor substrate 110. In one or more examples, the lower wiring structure PBEOL may be a BSPDN structure that transmits power to the first semiconductor chip 100 from the outside.

The lower wiring structure PBEOL may include a plurality of lower wiring lines 172, a plurality of lower wiring vias 174, and an insulating layer 176 between lower interconnections surrounding the lower wiring lines 172 and the lower wiring vias 174. The plurality of lower wiring vias 174 may electrically connect the plurality of lower wiring lines 172 to the plurality of micro through electrodes 162. In one or more embodiments, when a plurality of lower wiring lines 172 have two or more wiring layers, some of the plurality of lower wiring vias 174 may electrically connect lower wiring lines 172 located at different vertical levels among the plurality of lower wiring lines 172, that is, lower wiring lines 172 located on different wiring layers.

The wiring layer refers to an electrical path extending in a plane at the same vertical level. In one or more examples, the upper wiring structure SBEOL may have more interconnection layers than the lower wiring structure PBEOL. The thickness of the upper wiring structure SBEOL in the vertical direction (e.g., Z direction) may be greater than the thickness of the lower wiring structure PBEOL.

A plurality of chip connection terminals 180 may be disposed below the lower wiring structure PBEOL. The plurality of chip connection terminals 180 may electrically connect one portion of the plurality of lower wiring lines 172 to the outside. For example, the plurality of chip connection terminals 180 may be bumps or solder balls.

In one or more examples, the first semiconductor chip 100 may exchange signals excluding power, such as data signals and control signals, with the outside through the upper wiring structure SBEOL and may receive power from external sources through the lower wiring structure PBEOL. Therefore, the upper wiring structure SBEOL may be referred to as a signal wiring structure and the lower wiring structure PBEOL may be referred to a power wiring structure. In one or more embodiments, the first semiconductor chip 100 may receive both power and ground from the outside through the lower wiring structure PBEOL.

The first semiconductor chip 100 according to one or more embodiments may exchange signals excluding power, such as data signals and control signals, with the outside through the upper wiring structure SBEOL disposed on the front side of the semiconductor substrate 110 and may receive power from the outside through the lower wiring structure PBEOL disposed on the backside surface 110b of the semiconductor substrate 110. Accordingly, in the first semiconductor chip 100, signals and power may be transmitted through the upper portion and lower portion of the first semiconductor chip 100, respectively, thereby minimizing interference between signals and power. In addition, even if the integration degree of the first semiconductor chip 100 increases, such as a decrease in the width of the plurality of nanosheet regions NS, the signals and the power may be stably transmitted to the first semiconductor chip 100.

The second semiconductor chip 200 may have the same structure as the first semiconductor chip 100, and the detailed structure of the second semiconductor chip 200 may be understood by referring to the structure of the first semiconductor chip 100 of FIG. 2.

In one or more embodiments, the first semiconductor chip 100 and the second semiconductor chip 200 may be configured as a set of memory chips that exchange data with each other.

In one or more examples, the memory chip refers to a semiconductor chip for storing information. For example, the first semiconductor chip 100 may be a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, a resistive random access memory (RRAM) chip, or any other suitable memory structure known to one of ordinary skill in the art.

In one or more embodiments, the first semiconductor chip 100 and the second semiconductor chip 200 may be logic semiconductor chips.

The logic semiconductor chip refers to a semiconductor chip that performs logical operations. For example, the logic semiconductor chip may include logic cells. The logic cell may be configured in various ways, including a plurality of circuit elements, such as transistors and resistors. The logic cell may consist of, for example, an AND, a NAND, an OR, NOR, an exclusive OR (XOR), exclusive NOR (XNOR), an inverter (INV), an adder (ADD), a buffer (BUF), a delay (DLY), a filter (FIL), a Multiplexer (MXT/MXIT), an OR/AND/Inverter (OAI), AND/OR (AO), an AND/OR/Inverter (AOI), a D flip-flop, a reset flip-flop, a master-slave flip-flop, a latch, etc., and the logic cells may constitute standard cells that perform desired logical functions such as counters, buffers, etc.

For example, the first semiconductor chip 100 or the second semiconductor chip 200 may be a central processing unit (CPU) chip, a graphics processing unit (GPU) chip, or an application processor (AP) chip. A plurality of nanosheet regions NS and a plurality of gate lines 140 may constitute a semiconductor device that functions as a CPU, GPU, or AP on the active side of the semiconductor substrate 110.

In one or more examples, the first semiconductor chip 100 and the second semiconductor chip 200 may be composed of different types of semiconductor chips. Referring to FIG. 1, in one or more embodiments, the first semiconductor chip 100 and the second semiconductor chip 200 may be a semiconductor chip set composed of semiconductor chips of the same height in terms of package structure.

FIG. 3 is a cross-sectional view of a semiconductor package 10A including a first semiconductor chip and a second semiconductor chip, according to one or more embodiments.

Referring to FIGS. 2 and 3, the first semiconductor chip 100 and the second semiconductor chip 200 may be disposed on the lower redistribution layer substrate 310. The first semiconductor chip 100 and the second semiconductor chip 200 may be arranged to be spaced apart from each other on the lower redistribution layer substrate 310. A first molding member 430 may be disposed between the first expansion layer 400, the first semiconductor chip 100, and the second semiconductor chip 200. The first molding member 430 may fill the space between the chip connection terminals 180 on the side and lower surfaces of the first semiconductor chip 100 and the second semiconductor chip 200. However, in some embodiments, an underfill may be filled between the chip connection terminal 180 on the lower surface of the first semiconductor chip 100 and the chip connection terminal on the lower surface of the second semiconductor chip 200, and the first molding member 430 may cover the side surfaces of the first semiconductor chip 100, the second semiconductor chip 200, and the underfill.

The first semiconductor chip 100 and the second semiconductor chip 200 may each be electrically connected to the lower conductive structure 314 through chip connection terminals 180. The first semiconductor chip 100 may receive power from the outside through the plurality of chip connection terminals 180, the lower wiring structure PBEOL, the plurality of micro through electrodes 162, and a plurality of buried power rails BPR. The second semiconductor chip 200 may also receive power from the outside in a similar manner to the first semiconductor chip 100.

A first upper redistribution layer substrate 320 is disposed on the first expansion layer 400, the first semiconductor chip 100, and the second semiconductor chip 200, and a second expansion layer 600 and an interposer 500 are disposed on the first upper redistribution layer substrate 320. The first semiconductor chip 100 and the second semiconductor chip 200 may be electrically connected to each other through the first upper redistribution layer substrate 320 and the interposer 500. The first semiconductor chip 100 and the second semiconductor chip 200 may exchange signals excluding power, such as data signals and control signals, with each other through a first upper conductive structure 324 and the interposer 500. That is, the first upper redistribution layer substrate 320 may be electrically connected to the first expansion layer 400, the first semiconductor chip 100, and the second semiconductor chip 200 at the lower portion thereof, and may be electrically connected to the second expansion layer and the interposer at the upper portion thereof.

Referring to FIG. 3, a second upper redistribution layer substrate 330 may be disposed on the second expansion layer 600. The second upper redistribution layer substrate 330 may rewire a plurality of second conductive connection structures 620 of the second expansion layer 600. In one or more examples, the second upper redistribution layer substrate 330 may include a second upper body insulating layer 332 and a second upper conductive structure 334.

The second upper body insulating layer 332 may be formed of an insulating material, for example, PID resin, and may further include an inorganic filler. The second upper conductive structure 334 may be made of metal or an alloy thereof.

The second upper conductive structure 334 may be connected to the second conductive connection structure 620 of the second expansion layer 600. The second upper conductive structure 334 may be electrically connected to the first upper conductive structure 324 through a plurality of second conductive connection structures 620.

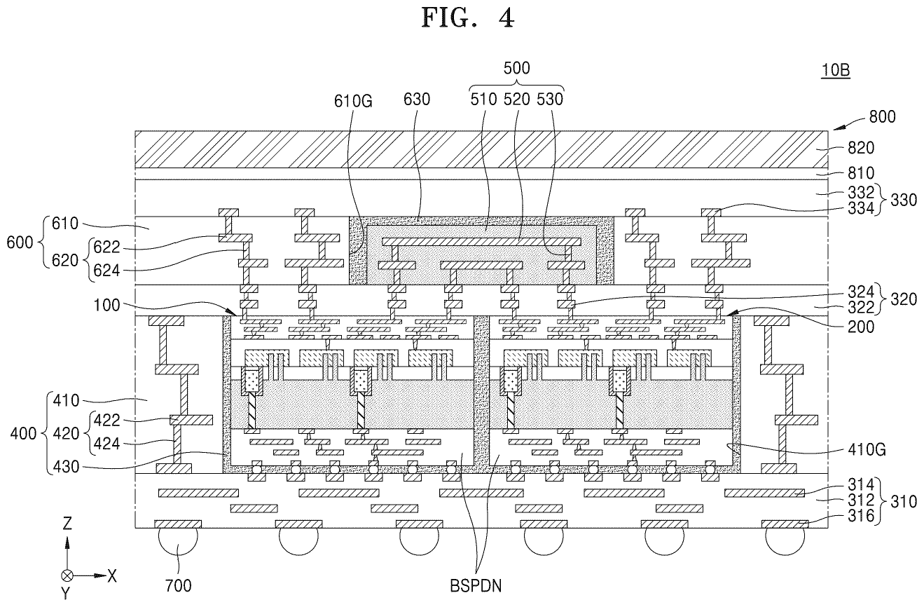

FIG. 4 is a cross-sectional view of a semiconductor package 10B including a heat dissipation structure, according to one or more embodiments.

Referring to FIG. 4, a heat dissipation structure 800 may be disposed on the upper portion of the interposer 500. In detail, the heat dissipation structure 800 may be attached to a second upper redistribution layer substrate 330 and placed on top of the interposer 500.

The heat dissipation structure 800 may include an adhesive layer 810 and a heat dissipation portion 820. The heat dissipation portion 820 may be laminated on the second upper redistribution layer substrate 330 through the adhesive layer 810. The adhesive layer 810 may include a material with high thermal conductivity. For example, the adhesive layer 810 may be formed of thermal interface material (TIM) or thermally conductive resin. The TIM may include materials with high thermal conductivity, that is, low thermal resistance, such as grease, tape, elastomer filling pad, and phase transfer material. The heat dissipation portion 820 may include a heat sink or a heat slug.

In FIG. 4, the heat dissipation structure 800 is shown to cover the entire upper surface of the second upper redistribution layer substrate 330, but is not limited thereto. The heat dissipation structure 800 may be arranged to cover a portion of the upper surface of the second upper redistribution layer substrate 330.

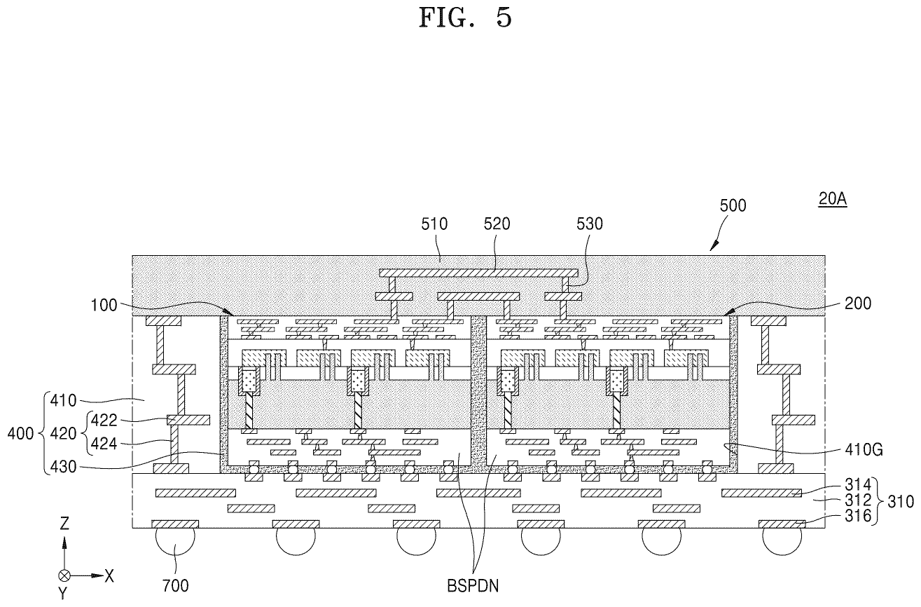

FIG. 5 is a cross-sectional view showing a semiconductor package 20A according to one or more embodiments. In detail, in FIG. 5, the same reference numerals as in FIGS. 1 to 4 indicate the same components, and the description already given thereof may be referred to in FIGS. 1 to 4.

Referring to FIG. 5, the semiconductor package 20A according to one or more embodiments may include a first semiconductor chip 100, a second semiconductor chip 200, a lower redistribution layer substrate 310, an expansion layer 400, an interposer 500, and a plurality of external connection terminals 700. The expansion layer 400 of FIG. 5 corresponds to the first expansion layer 400 in the semiconductor package 10A of FIG. 3 and includes the same components as the first expansion layer 400 of FIG. 3. Therefore, the expansion layer 400 of FIG. 5 uses the same reference numeral as the first expansion layer 400 of FIG. 3.

The first semiconductor chip 100 and the second semiconductor chip 200 may be arranged side-by-side on the lower redistribution layer substrate 310. For example, the first semiconductor chip 100 and the second semiconductor chip 200 may be arranged to be spaced apart from each other at a predetermined distance on the lower redistribution layer substrate 310. The first semiconductor chip 100 and the second semiconductor chip 200 may each have a BSPDN structure disposed in the lower portion of the first semiconductor chip 100 and the second semiconductor chip 200 and may receive power through the lower redistribution layer substrate 310. Therefore, embodiments of the present disclosure provide a semiconductor package including multi chipsets to which BSPDN is applied, and including a plurality of semiconductor chips arranged side-by-side. By applying the BSPDN technology, each semiconductor chip may receive power from the outside through the lower surface, thereby reducing IR drop and securing power gain. Furthermore, each semiconductor chip may transmit signals to each other through an interposer disposed on the upper portion of a plurality of semiconductor chips, thereby ensuring communication performance.

The expansion layer 400 may be disposed outside the first semiconductor chip 100 and the second semiconductor chip 200 on the lower redistribution layer substrate 310. In one or more examples, the expansion layer 400 may include an insulating layer 410 and a plurality of conductive connection structures 420 buried in the insulating layer 410. For example, the expansion layer 400 may be an ETS in which a circuit pattern is buried in an insulating material.

A molding member 430 may be disposed on the lower redistribution layer substrate 310 to surround the first semiconductor chip 100 and the second semiconductor chip 200. In one or more examples, the molding member 430 of FIG. 5 corresponds to the first molding member 430 in the semiconductor package 10A of FIG. 3 and includes the same components as the first molding member 430 of FIG. 3. Therefore, the molding member 430 of FIG. 5 uses the same reference numeral as the first molding member 430 of FIG. 3. The molding member 430 may fill the space between the expansion layer 400, the first semiconductor chip 100, and the second semiconductor chip 200.

The interposer 500 may be disposed on upper portion of the first semiconductor chip 100 and the second semiconductor chip 200 to electrically connect the first semiconductor chip 100 to the second semiconductor chip 200. The interposer 500 may be disposed on the first semiconductor chip 100 and the second semiconductor chip 200 so as to completely cover the upper surface of the first semiconductor chip 100 and the upper surface of the second semiconductor chip 200. The interposer 500 may be disposed over the expansion layer 400. In one or more examples, the interposer 500 may be extended and disposed to completely cover the expansion layer 400, the first semiconductor chip 100, and the second semiconductor chip 200. In one or more examples, the lower surface of the interposer 500 may form the same plane as the upper surface of the expansion layer 400, the upper surface of the first semiconductor chip 100, the upper surface of the second semiconductor chip 200, and the upper surface of the molding member 430.

The interposer 500 may include a silicon substrate 510, a wiring line 520, and a wiring via 530. The wiring line 520 may include a plurality of layers within the silicon substrate 510. The wiring via 530 may penetrate at least a portion of the silicon substrate 510 to electrically connect the wiring lines 520. For example, the interposer 500 may be a silicon interposer layer.

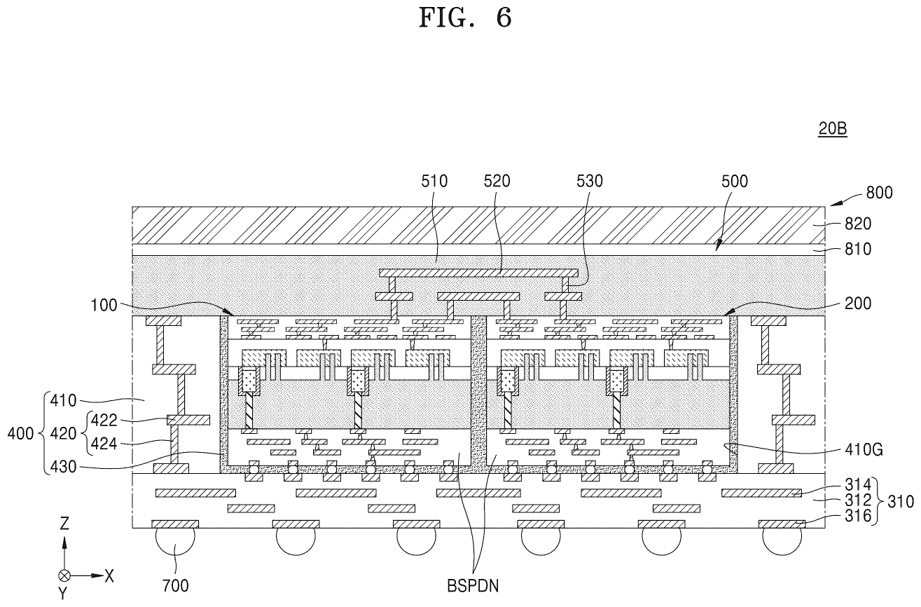

FIG. 6 is a cross-sectional view showing a semiconductor package 20B further including a heat dissipation structure in the semiconductor package 20A of FIG. 5.

Referring to FIG. 6, a heat dissipation structure 800 may be disposed on the upper portion of the interposer 500. Here, the heat dissipation structure 800 may include the same components as the heat dissipation structure 800 of FIG. 4. The heat dissipation structure 800 may include an adhesive layer 810 made of a material with high thermal conductivity, such as TIM, or thermally conductive resin, and a heat dissipation portion 820 that may include a heat sink or heat slug.

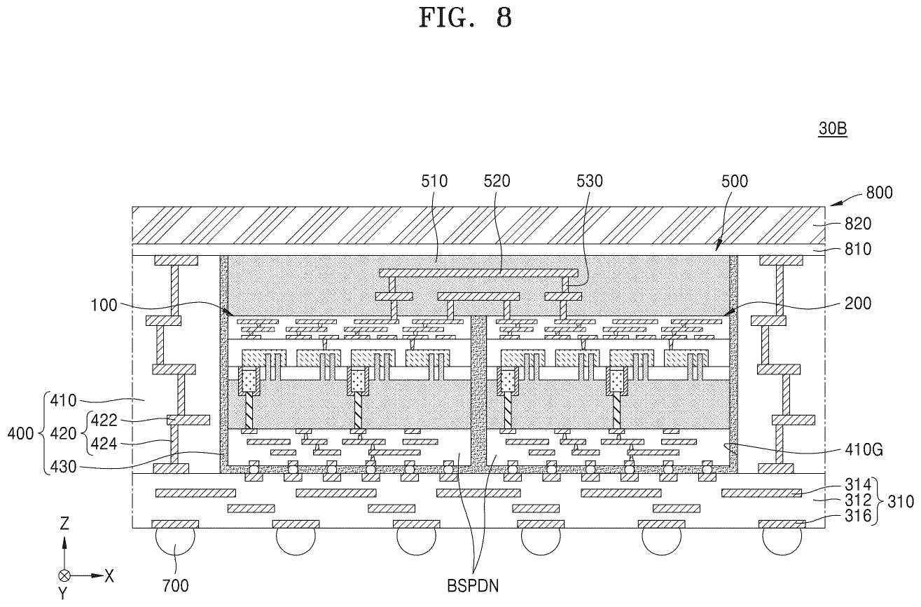

The heat dissipation structure 800 may be arranged to cover the upper portion of the interposer 500. In FIG. 8, the heat dissipation structure 800 is shown to cover the entire upper portion of the interposer 500, but is not limited to thereto. The heat dissipation structure 800 may be arranged to cover a portion of the upper part of the interposer 500.

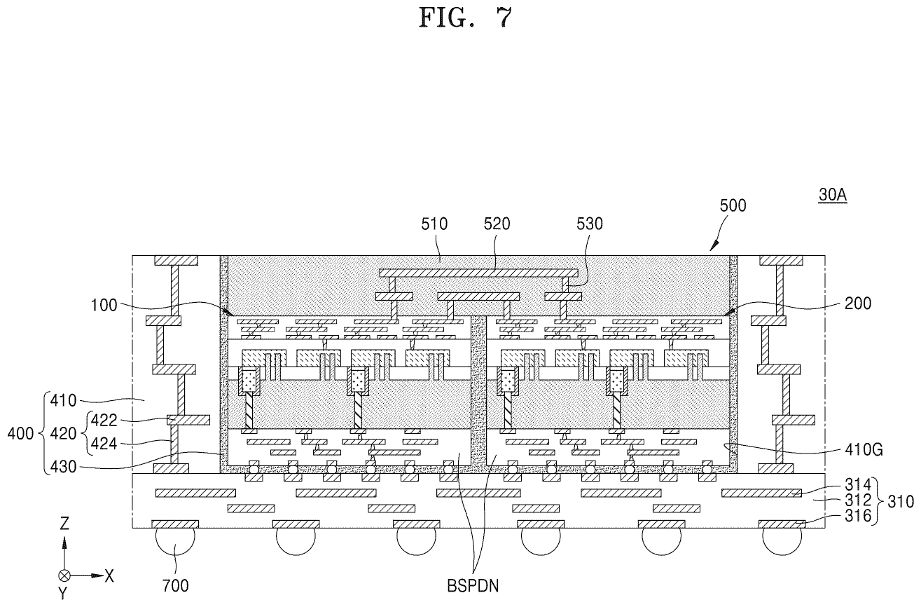

FIG. 7 is a cross-sectional view showing a semiconductor package 30A according to one or more embodiments. In detail, in FIG. 7, the same reference numerals as in FIG. 5 indicate the same components, and the description already given thereof may be referred to in FIG. 5.

Referring to FIG. 7, the semiconductor package 30A according to one or more embodiments may have a similar structure to the semiconductor package 20A of FIG. 5, but may have some differences in the arrangement of the expansion layer 400 and the interposer 500, which are explained in further detail below.

In one or more examples, the interposer 500 may be disposed on the first semiconductor chip 100 and the second semiconductor chip 200 and may electrically connect the first semiconductor chip 100 to the second semiconductor chip 200. The interposer 500 may be disposed on the first semiconductor chip 100 and the second semiconductor chip 200 so as to completely cover the upper surface of the first semiconductor chip and the upper surface of the second semiconductor chip.

In one or more examples, the expansion layer 400 may be disposed outside the first semiconductor chip 100, the second semiconductor chip 200, and the interposer 500 on the lower redistribution layer substrate 310. The height of the expansion layer 400 may be equal to the sum of the height of the interposer 500 and the height of the first semiconductor chip 100 or the second semiconductor chip 200. For example, the sidewall of the expansion layer 400 may be arranged to face the sidewall of the interposer 500.

In one or more examples, the expansion layer 400 may include an insulating layer 410 and a plurality of conductive connection structures 420 embedded in the insulating layer 410. For example, the expansion layer 400 may be an ETS in which a circuit pattern is buried in an insulating material.

In one or more examples, the upper surface of the interposer 500 may form the same plane as the upper surface of the expansion layer 400, and the lower surface of the interposer 500 may form the same plane as the upper surface of the first semiconductor chip 100 and the upper surface of the second semiconductor chip 200.

The molding member 430 may be disposed on the lower redistribution layer substrate 310 to surround the first semiconductor chip 100, the second semiconductor chip 200, and the interposer 500. The molding member 430 may fill a space between the expansion layer 400, the first semiconductor chip 100, the second semiconductor chip 200, and the interposer 500. The upper surface of the molding member 430 may form the same plane as the upper surface of the interposer 500 and the upper surface of the expansion layer 400.

FIG. 8 is a cross-sectional view showing a semiconductor package 30B further including a heat dissipation structure in the semiconductor package 30A of FIG. 7.

Referring to FIG. 8, a heat dissipation structure 800 may be disposed on the upper portion of the interposer 500. In one or more examples, the heat dissipation structure 800 may include the same components as the heat dissipation structure 800 of FIGS. 4 and 6.

The heat dissipation structure 800 may be arranged to cover both the upper portion of the interposer 500 and the upper portion of the expansion layer 400. However, the heat dissipation structure 800 is not limited thereto, and the heat dissipation structure 800 may be arranged to cover only the upper portion of the interposer 500, or may be arranged to cover only a portion of the upper portion of the interposer 500 and the upper portion of the expansion layer 400.

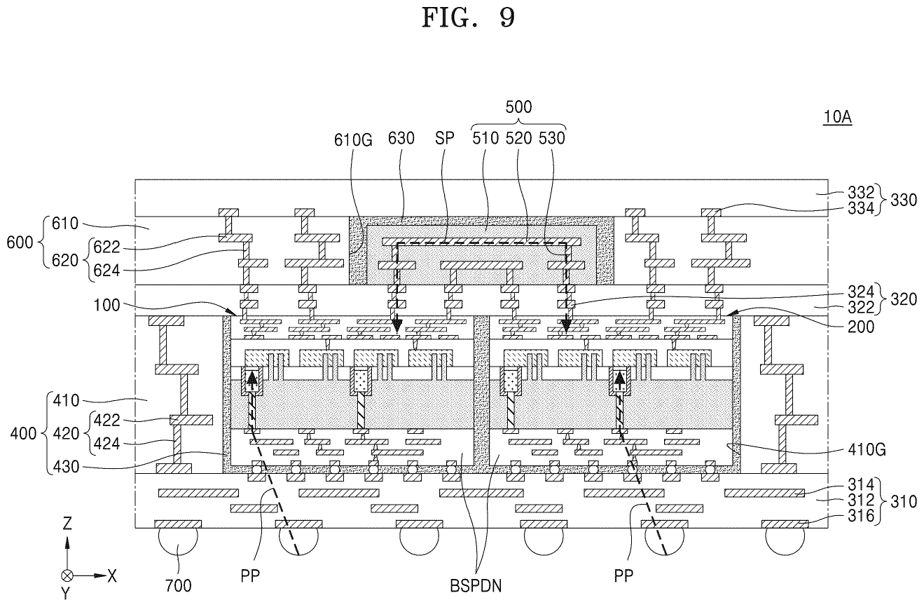

FIG. 9 is a cross-sectional view illustrating the operation of a first semiconductor chip and a second semiconductor chip in a semiconductor package according to one or more embodiments. In detail, FIG. 9 is a cross-sectional view explaining the operation of the semiconductor package 10A shown in FIG. 3, the same reference numerals as in FIG. 3 indicate the same components, and the description thereof may be referred to in FIG. 3.

Referring to FIG. 9, when the semiconductor package 10A operates, a power path PP and a signal path SP may be generated. The first semiconductor chip 100 and the second semiconductor chip 200 may each receive power from the outside through the power path PP. The first semiconductor chip 100 and the second semiconductor chip 200 may exchange signals with each other through the signal path SP.

In one or more embodiments, the first semiconductor chip 100 may have the same power path PP as the second semiconductor chip 200. Hereinafter, the description focuses on the power path PP of the first semiconductor chip 100.

The power path PP of the first semiconductor chip 100 may be generated along external connection terminals 700, a plurality of external connection pads 316, a lower conductive structure 314 of the lower redistribution layer substrate 310, a plurality of chip connection terminals 180, a lower wiring structure PBEOL, a plurality of micro through electrodes 162, and a plurality of buried power rails BPR.

The signal path SP may be generated along the upper wiring structure SBEOL of the first semiconductor chip 100, the first upper conductive structure 324 of the first upper redistribution layer substrate 320, the wiring lines 520 and wiring vias 530 of the interposer 500, the first upper conductive structure 324 of the first upper redistribution layer substrate 320, and a second upper wiring structure of the second semiconductor chip 200. Because the first semiconductor chip 100 and the second semiconductor chip 200 may exchange signals with each other, the signal path SP may be generated in the opposite direction.

The power path PP and signal path SP within the semiconductor package 10A are separated from each other, thereby preventing signal interference due to power and improving the operational reliability of the semiconductor package 10A.

In one or more examples, the operations of the semiconductor packages 20 and 30 of FIGS. 5 to 8 are may be similar to the operations of the semiconductor package 10A described with reference to FIG. 9. In one or more examples, the power path PP of the semiconductor packages 20 and 30 of FIGS. 5 to 8 may be generated identically to the power path PP of the semiconductor package 10A of FIG. 9. However, because the first upper redistribution layer substrate 320 is omitted in the semiconductor packages of 20 and 30 FIGS. 5 to 8, the signal path SP may be generated along the upper wiring structure SBEOL of the first semiconductor chip 100, the wiring line 520 and wiring via 530 of the interposer 500, and the second upper wiring structure of the second semiconductor chip 200. The signal path SP may also be generated in the opposite direction.

Even in the case of the semiconductor packages 20 and 30 of FIGS. 5 to 8, the power path PP and the signal path SP are separated from each other, thereby preventing signal interference due to power and improving the operation reliability of the semiconductor packages 20 and 30.

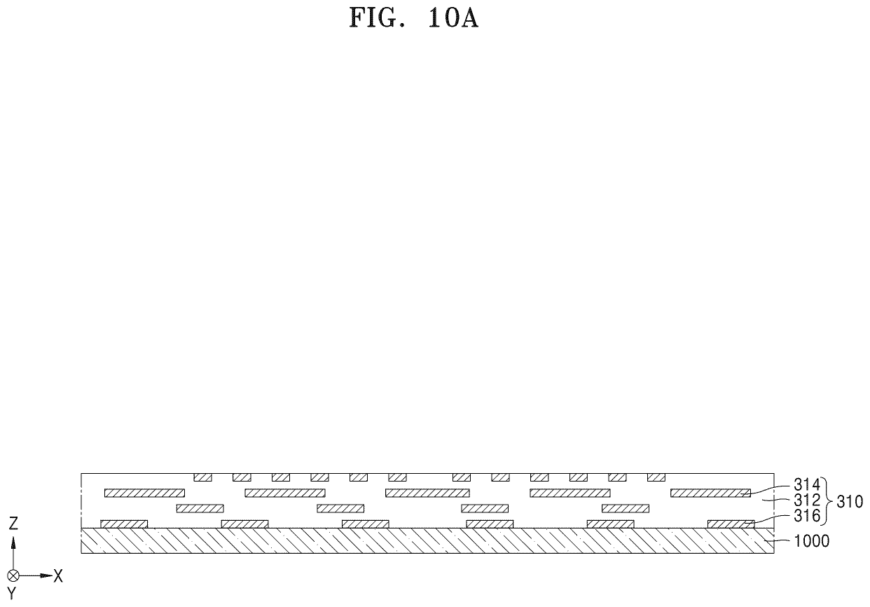

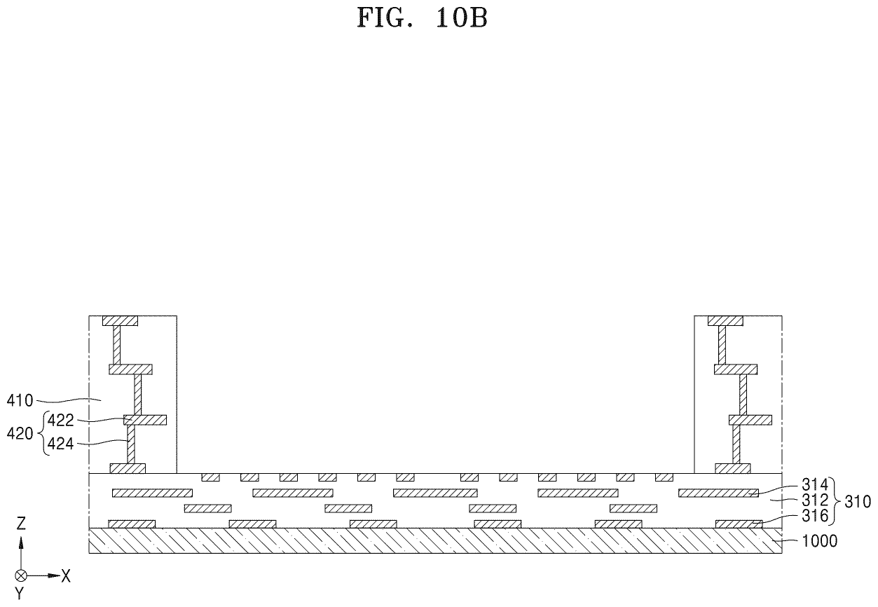

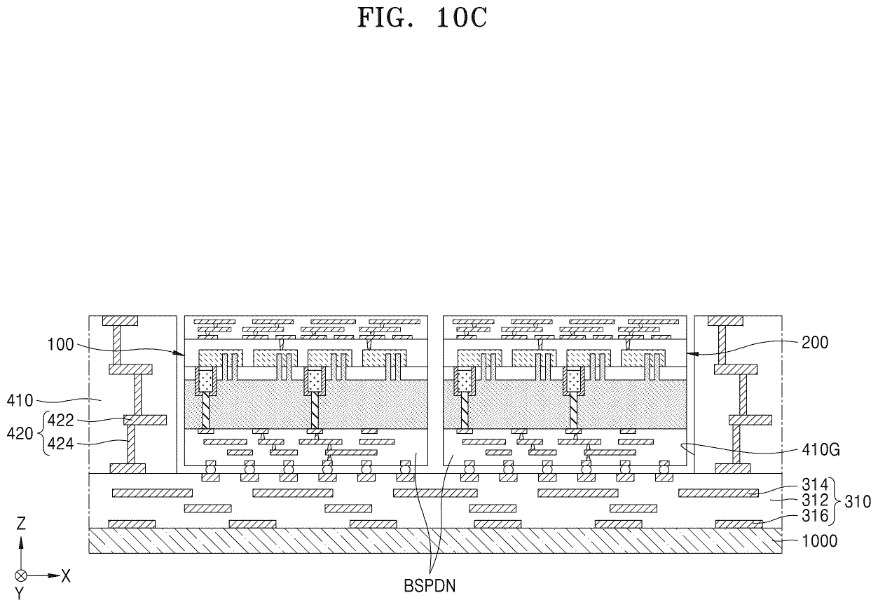

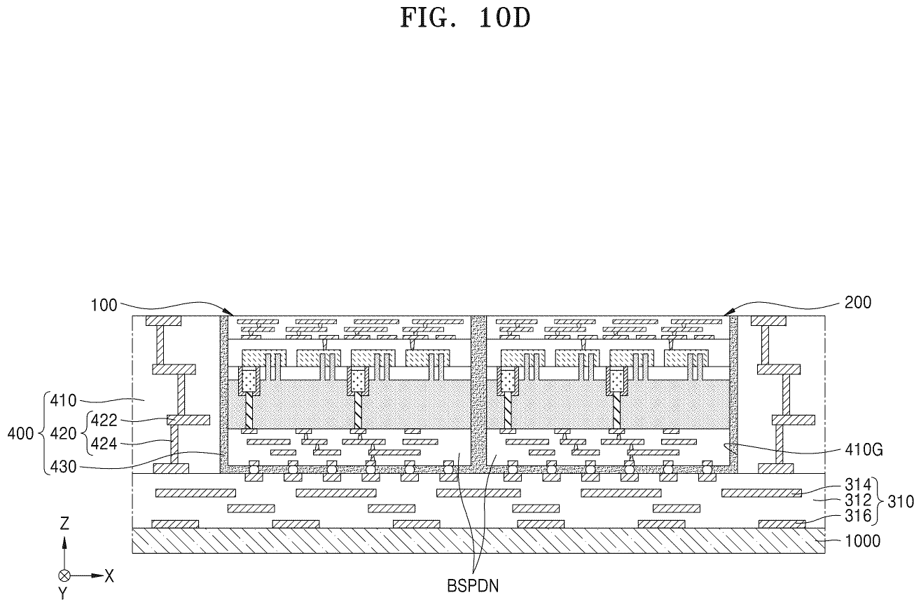

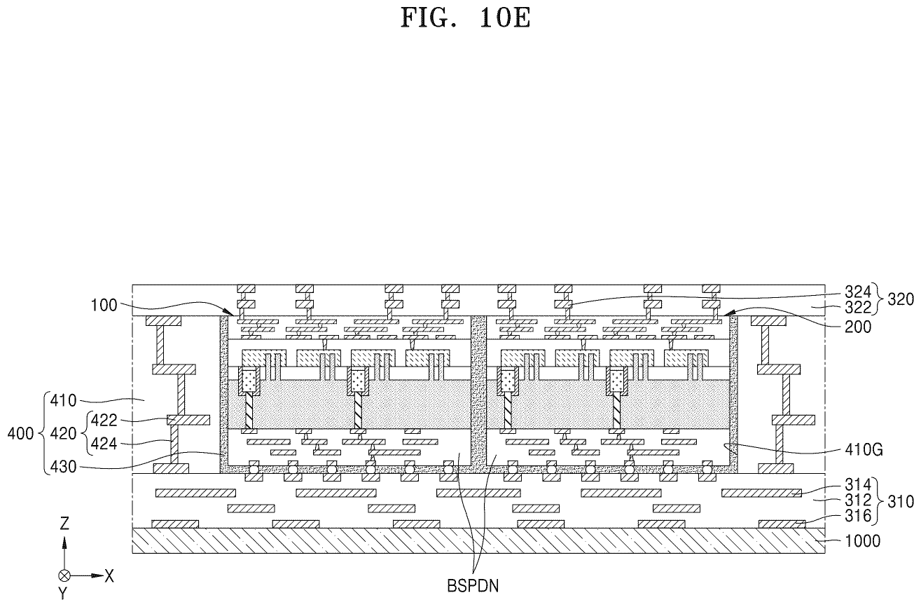

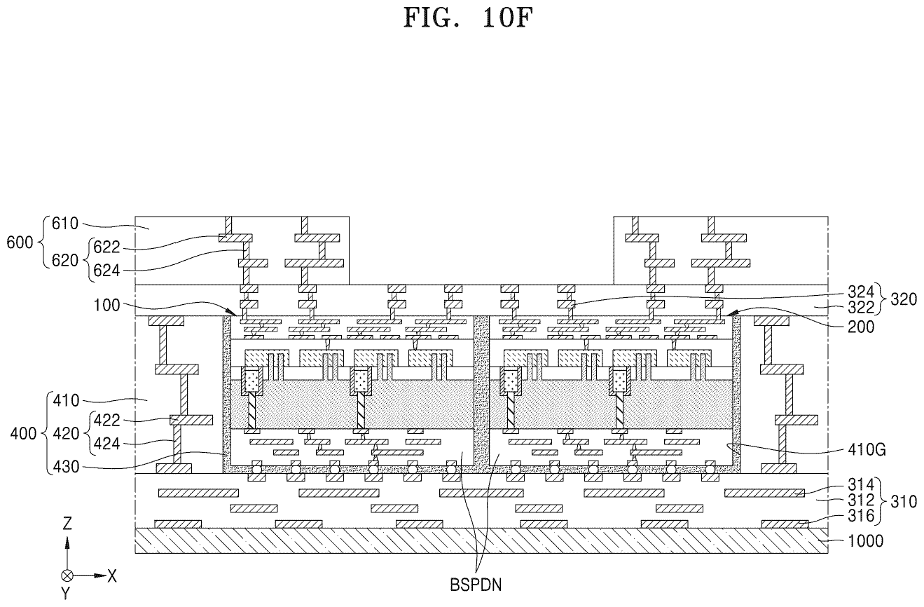

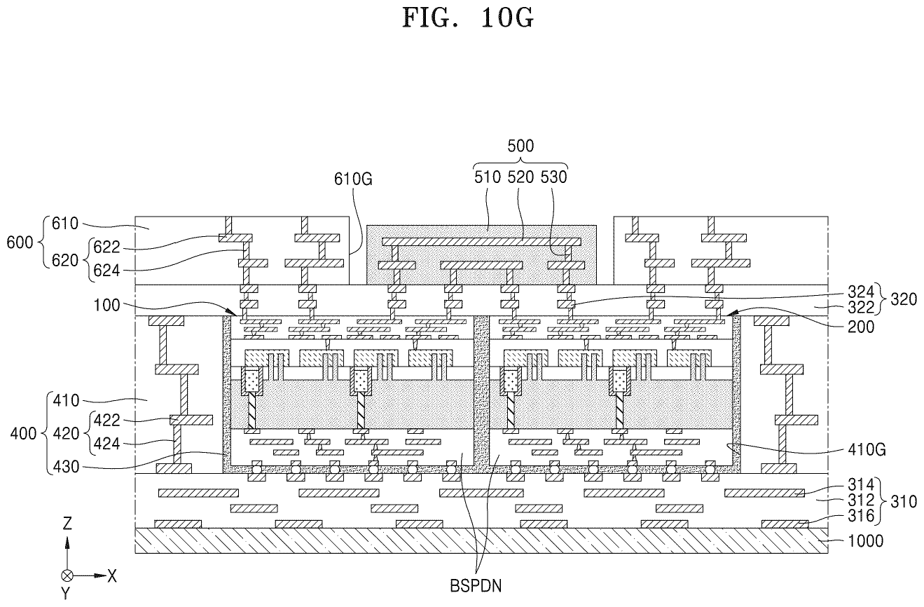

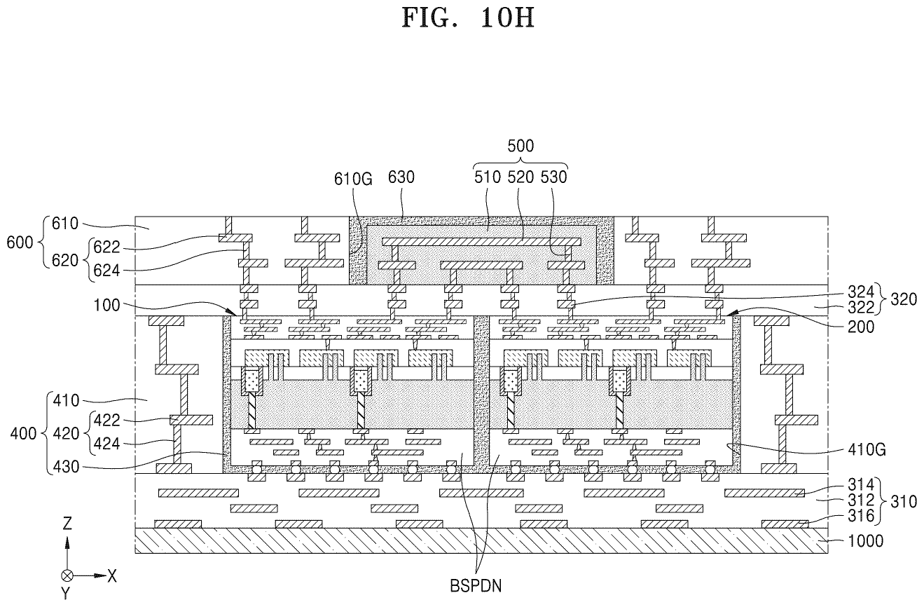

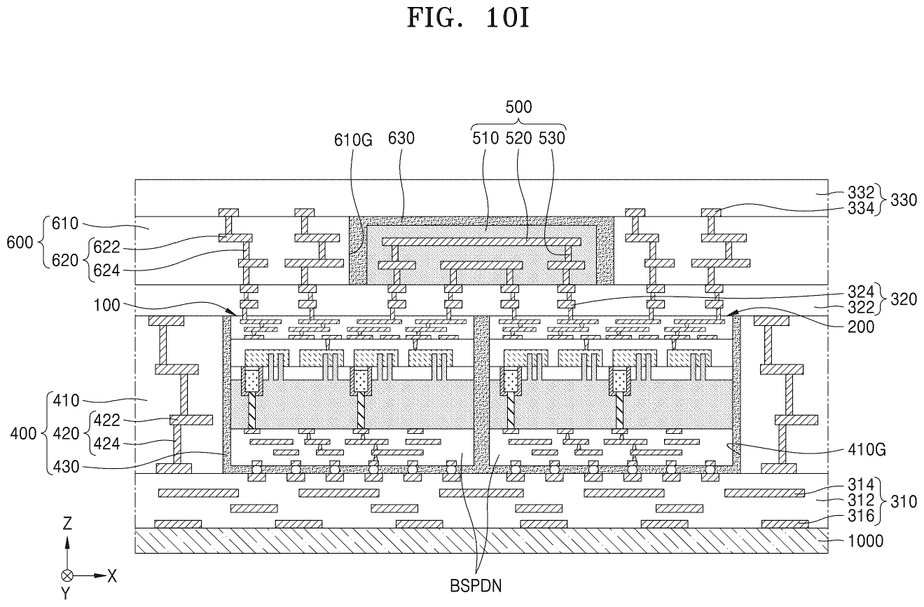

FIGS. 10A to 10I are cross-sectional views schematically showing the process of manufacturing the semiconductor package 10A of FIG. 3, according to one or more embodiments.

Referring to FIG. 10A, a lower redistribution layer substrate 310 is formed on a support substrate 1000. The lower redistribution layer substrate 310 may include a lower body insulating layer 312 and a lower conductive structure 314. The lower surface of the body insulating layer 312 may include a plurality of external connection pads 316 electrically connected to the lower conductive structure 314.

Referring to FIG. 10B with FIG. 3, a first expansion layer 400 is formed on the lower redistribution layer substrate 310. The first expansion layer 400 may include a first insulating layer 410 and a plurality of first conductive connection structures 420 embedded in the first insulating layer 410. The plurality of first conductive connection structures 420 may include a plurality of first conductive layers 422 and a plurality of first vertical vias 424.

The first expansion layer 400 may be formed on the lower redistribution layer substrate 310 to form the inner space 410G. In one or more examples, a plurality of first expansion layers 400 may be formed on the lower redistribution layer substrate 310 to be spaced apart from each other to form an inner space 410G.

In one or more examples, after forming the first expansion layer 400 on the lower redistribution layer substrate 310, dry etching, wet etching, screen printing, drill bit, or laser drilling processes may be used to form the inner space 410G penetrating from the upper surface to the lower surface of the first expansion layer 400.

Referring to FIG. 10C, the first semiconductor chip 100 and the second semiconductor chip 200 may be attached to the lower redistribution layer substrate 310 so as to be spaced apart from each other in the inner space 410G.

Referring to FIG. 10D, a first molding member 430 is formed to fill the first inner space 410G. The first molding member 430 may be disposed on the lower redistribution layer substrate 310 to surround the first semiconductor chip 100 and the second semiconductor chip 200. The first molding member 430 may be formed to fill a space between the first expansion layer 400, the first semiconductor chip 100, and the second semiconductor chip 200 and surround the plurality of chip connection terminals 180. In one or more embodiments, after the first molding member 430 is formed to cover the upper surfaces of the first semiconductor chip 100, the second semiconductor chip 200, the first insulating layer 410, and the first conductive connection structure 420, the first molding member 430 may be formed by removing a portion of the upper side of the first molding member 430 until the upper surfaces of the first semiconductor chip 100 and the second semiconductor chip 200 are exposed.

Referring to FIG. 10E, a first upper redistribution layer substrate 320 is formed on the first semiconductor chip 100, the second semiconductor chip 200, and the first expansion layer 400. The first upper redistribution layer substrate 320 may include a first upper body insulating layer 322 and a first upper conductive structure 324. The first upper conductive structure 324 is formed to be connected to the upper wiring structure of the first semiconductor chip 100 and the upper wiring structure of the second semiconductor chip 200. In one or more examples, a portion of the first upper conductive structure 324 may be formed to be connected to the first conductive connection structure 420 of the first expansion layer 400.

Referring to FIG. 10F, a second expansion layer 600 is formed on the first upper redistribution layer substrate 320. The second expansion layer 600 may include a second insulating layer 610 and a plurality of second conductive connection structures 620 penetrating the interior of the second insulating layer 610. The plurality of second conductive connection structures 620 may include a plurality of second conductive layers 622 and a plurality of second vertical vias 624.

The second expansion layer 600 may be formed on the first upper redistribution layer substrate 320 to form the inner space 610G. In one or more examples, a plurality of second expansion layers 600 may be formed on the first upper redistribution layer substrate 320 to be spaced apart from each other to form an inner space 610G.

In one or more examples, after forming the second expansion layer 600 on the first upper redistribution layer substrate 320, dry etching, wet etching, screen printing, drill bit, or laser drilling processes may be used to form the inner space 610G penetrating from the upper surface to the lower surface of the second expansion layer 600.

Referring to FIG. 10G, the interposer 500 may be attached to the first upper redistribution layer substrate 320 to be located within the second inner space 610G.

Referring to FIG. 10H, a second molding member 630 is formed to fill the second inner space 610G. The second molding member 630 may be disposed on the first upper redistribution layer substrate 320 to surround the interposer 500. The second molding member 630 may fill the space between the second expansion layer 600 and the interposer 500. The second molding member 630 may be formed so that the upper surface of the second molding member 630 is on the same plane as the upper surfaces of the second insulating layer 610 and the plurality of second conductive connection structures 620. In one or more embodiments, the second molding member 630 is formed to cover the upper surfaces of the interposer 500, the second insulating layer 610, and the second conductive connection structure 620, and then the second molding member 630 may be formed by removing a portion of the upper side of the second molding member 630 until the upper surfaces of the second insulating layer 610 and the plurality of second conductive connection structures 620 are exposed.

Referring to FIG. 10I, a second upper redistribution layer substrate 330 is formed on the second expansion layer 600. The second upper redistribution layer substrate 330 may include a second upper body insulating layer 332 and a second upper conductive structure 334.

Referring to FIGS. 101 and 3 together, a support substrate 1000 is removed from the lower redistribution layer substrate 310 to expose a plurality of external connection pads 316. A semiconductor package 10A is formed by attaching a plurality of external connection terminals 700 to the plurality of external connection pads 316.

The process of manufacturing the semiconductor package 20A of FIG. 5 according to one or more embodiments is not separately shown, but may be performed similarly to the process of manufacturing the semiconductor package 10A shown in FIGS. 10A to 10E. However, instead of the first upper redistribution layer substrate 320 of FIG. 10E, the interposer 500 may be disposed on the first semiconductor chip 100, the second semiconductor chip 200, and the expansion layer 400.

The process of manufacturing the semiconductor package 30A of FIG. 7 according to one embodiment is not separately shown, but may be performed similarly to the process of manufacturing the semiconductor package 10A shown in FIGS. 10A to 10D. However, in the process of FIG. 10C, the interposer 500 may be placed on the first semiconductor chip 100 and the second semiconductor chip 200, and the molding member 430 in FIG. 10D may be formed.

While the embodiments of the present disclosure have been particularly shown and described with reference to embodiments thereof, it will be understood that various changes in form and details may be made therein without departing from the spirit and scope of the following claims.

What is claimed is:

1. A semiconductor package comprising:
a first redistribution layer substrate having a lower conductive structure;
a first semiconductor chip and a second semiconductor chip electrically connected to the first redistribution layer substrate and arranged side-by-side on the first redistribution layer substrate; and
an interposer disposed over a portion of the first semiconductor chip and a portion of the second semiconductor chip to electrically connect the first semiconductor chip to the second semiconductor chip,
wherein the first semiconductor chip comprises a rear power distribution network structure in a lower portion of the first semiconductor chip, and the second semiconductor chip comprises a rear power distribution network structure in a lower portion of the second semiconductor chip.

2. The semiconductor package of claim 1, further comprising
a first expansion layer disposed on the first redistribution layer substrate and outside the first semiconductor chip and the second semiconductor chip,
wherein the first expansion layer comprises a plurality of first insulating layers, a plurality of first conductive layers, and a plurality of first vertical vias that penetrate the plurality of first insulating layers and vertically connect the plurality of first conductive layers to one another.

3. The semiconductor package of claim 2, further comprising:
a first molding member surrounding the first semiconductor chip and the second semiconductor chip, the first molding member filling a space between the first semiconductor chip and the first expansion layer and a space between the second semiconductor chip and the first expansion layer,
wherein a surface of the first semiconductor chip, a surface of the second semiconductor chip, a surface of the first expansion layer, and a surface of the first molding member are on the same plane.

4. The semiconductor package of claim 2, further comprising
a second redistribution layer substrate disposed on the first semiconductor chip, the second semiconductor chip, and the first expansion layer, and having a first conductive structure,
wherein the interposer is disposed on the second redistribution layer substrate and is disposed to vertically overlap a portion of the first semiconductor chip and a portion of the second semiconductor chip with the second redistribution layer substrate therebetween.

5. The semiconductor package of claim 4, further comprising
a second expansion layer disposed on the second redistribution layer substrate and outside the interposer,
wherein the second expansion layer comprises a plurality of second insulating layers, a plurality of second conductive layers, and a plurality of second vertical vias that penetrate the plurality of second insulating layers to vertically connect the plurality of second conductive layers to one another.

6. The semiconductor package of claim 5, wherein the second expansion layer is arranged to vertically overlap another portion of the first semiconductor chip and another portion of the second semiconductor chip.

7. The semiconductor package of claim 5, further comprising a second molding member surrounding an upper portion and sides of the interposer, the second molding member filling a space between the interposer and the second expansion layer.

8. The semiconductor package of claim 7, further comprising a third redistribution layer substrate disposed on the second expansion layer and the interposer and having a second upper conductive structure.

9. The semiconductor package of claim 8, wherein the second redistribution layer substrate is electrically connected to the first expansion layer, the first semiconductor chip, and the second semiconductor chip at a first portion of the second redistribution layer substrate and is electrically connected to the second expansion layer and the interposer at a second portion of the second redistribution layer substrate.

10. The semiconductor package of claim 1, wherein the first semiconductor chip and the second semiconductor chip each comprise:
a semiconductor substrate having a first side surface and a second side surface facing each other,
a wiring structure disposed on the first side surface of the semiconductor substrate and electrically connected to the interposer,
a buried power rail disposed on the semiconductor substrate, and
a micro through electrode electrically connecting the buried power rail to the rear power distribution network structure.

11. The semiconductor package of claim 10,
wherein the rear power distribution network structure of each of the first semiconductor chip and the second semiconductor chip comprises a plurality of wiring lines, an insulating layer between the plurality of wiring lines, and a plurality of wiring vias penetrating the insulating layer between the plurality of wiring lines to connect the plurality of wiring lines in a vertical direction to one another, and
wherein the first semiconductor chip and the second semiconductor chip are each electrically connected to the first redistribution layer substrate through the rear power distribution network structure of each of the first semiconductor chip and the second semiconductor chip.

12. The semiconductor package of claim 1, wherein the first semiconductor chip and the second semiconductor chip are composed of a set of memory chips that exchange data with each other.

13. The semiconductor package of claim 2, further comprising a heat dissipation structure disposed on an upper portion of the interposer.

14. A semiconductor package comprising:
a first redistribution layer substrate having a lower conductive structure;
a first semiconductor chip and a second semiconductor chip electrically connected to the first redistribution layer substrate and arranged side-by-side on the first redistribution layer substrate; and
an interposer disposed over the first semiconductor chip and the second semiconductor chip so as to completely cover a surface of the first semiconductor chip and a surface of the second semiconductor chip and electrically connecting the first semiconductor chip to the second semiconductor chip,
wherein the first semiconductor chip and the second semiconductor chip each comprise a rear power distribution network structure.

15. The semiconductor package of claim 14, further comprising
an expansion layer disposed on the first redistribution layer substrate and outside the first semiconductor chip and the second semiconductor chip,
wherein the expansion layer comprises a plurality of insulating layers, a plurality of conductive layers, and a plurality of vertical vias that penetrate the plurality of insulating layers and connect the plurality of conductive layers in a vertical direction to one another.

16. The semiconductor package of claim 14,
wherein the interposer is disposed over the expansion layer,
wherein a surface of the interposer, a surface of the expansion layer, the surface of the first semiconductor chip, and the surface of the second semiconductor chip are on the same plane.

17. The semiconductor package of claim 14,
wherein sidewalls of the interposer are arranged to face the sidewalls of the expansion layer,
wherein a first surface of the interposer and a surface of the expansion layer are on the same plane,
wherein a second surface of the interposer, the surface of the first semiconductor chip, and the surface of the second semiconductor chip are on the same plane.

18. The semiconductor package of claim 17, further comprising
a molding member surrounding the first semiconductor chip, the second semiconductor chip, and the interposer, the molding member filling a space between the first semiconductor chip, the second semiconductor chip, and the interposer and the expansion layer;
wherein a surface of the molding member forms the same plane as the first surface of the interposer and the surface of the expansion layer.

19. A semiconductor package comprising:
a first redistribution layer substrate comprising a conductive structure;
a plurality of external connection terminals disposed at a bottom of the first redistribution layer substrate;
a first semiconductor chip and a second semiconductor chip electrically connected to the first redistribution layer substrate and arranged side-by-side on the first redistribution layer substrate;
a first expansion layer disposed on the first redistribution layer substrate and outside the first semiconductor chip and the second semiconductor chip;
a first molding member surrounding the first semiconductor chip and the second semiconductor chip, the first molding member filling a space between the first semiconductor chip and the first expansion layer and a space between the first semiconductor chip and the first expansion layer,
a second redistribution layer substrate disposed on the first semiconductor chip, the second semiconductor chip, and the first expansion layer, the second redistribution layer comprising a conductive structure;
an interposer disposed on the second redistribution layer substrate, the interposer disposed to vertically overlap a portion of the first semiconductor chip and a portion of the second semiconductor chip with the second redistribution layer substrate therebetween, the interposer electrically connecting the first semiconductor chip to the second semiconductor chip;
a second expansion layer disposed on the second redistribution layer substrate, the second expansion layer disposed to overlap another portion of the first semiconductor chip and another portion of the second semiconductor chip, the second expansion layer disposed outside the interposer;
a second molding member surrounding an upper portion and sides of the interposer, the second molding member filling a space between the interposer and the second expansion layer; and
a third redistribution layer substrate disposed on the second expansion layer and the interposer, the third redistribution layer comprises a second upper conductive structure,
wherein the first semiconductor chip comprises a rear power distribution network structure in a lower portion of the first semiconductor chip, and the second semiconductor chip comprises a rear power distribution network structure in a lower portion of the second semiconductor chip, and
wherein the second redistribution layer substrate is electrically connected to the first expansion layer, the first semiconductor chip, and the second semiconductor chip at a first portion of the second redistribution layer substrate and is electrically connected to the second expansion layer and the interposer at a second portion of the second redistribution layer substrate.

20. The semiconductor package of claim 19, wherein the first semiconductor chip and the second semiconductor chip each comprise:
a semiconductor substrate having a first side surface and a second side surface facing each other;
a wiring structure disposed on the first side surface of the semiconductor substrate and electrically connected to the interposer;
a buried power rail disposed on the semiconductor substrate; and
a micro through electrode electrically connecting the buried power rail to the rear power distribution network structure.
